(19) United States
(12) Patent Application Publication
(10) Pub. No.: US 2019/0006573 A1
(43) Pub. Date: Jan. 3, 2019

(54) HIGH TEMPERATURE SUPERCONDUCTORS

(71) Applicant: Eastern Plus, LLC, Cleveland, OH (US)

(72) Inventors: Dong Zhao, Santa Clara, CA (US); George Jin Zhao, Cleveland, OH (US)

(21) Appl. No.: 16/126,599

(22) Filed: Sep. 10, 2018

Related U.S. Application Data
(62) Division of application No. 15/077,683, filed on Mar. 22, 2016.

(51) Int. Cl. H01L 39/12; C01F 15/00; C01F 17/00; H01L 39/00

(52) U.S. Cl. CPC H01L 39/12; C01P 2006/40; C01F 15/00; C01P 2002/77; C01P 2002/76; H01L 39/005; C01F 17/00

(57) ABSTRACT

This disclosure will describe a novel finding and make the claim for the first time on a group of old compounds and formulated new compounds. These compounds have superconducting property at high temperatures, i.e., 151 K or higher. Several compounds were prepared, though not well-purified, at around middle of 1900s. Their chemical, structural, electric and magnetic properties were studied and reported but their superconducting property has not been known and has never been exploited because the idea of type-II superconductivity was not proposed at that time. The experiments to further verify their high temperature superconductivity require the utilization of sophisticated facilities on synthesizing highly pure compounds and the deregulation from government security authorities on purchasing the starting materials.

### CROSS-REFERENCE TO RELATED APPLICATIONS

This application is a divisional of co-pending U.S. application Ser. No. 15/077,683, filed on Mar. 22, 2016. This prior application is incorporated herein by reference for all purposes.

### TECHNICAL FIELD

The present invention provides a group of compounds that have the electric superconducting property at 151 K or higher that, we believe, have the potential to reach a superconducting transition (critical) temperature (Tc) of the room temperature or even higher. Here, 151 K is the temperature defined as the low end of the Tc for the superconductors of this disclosure because no stable superconductor reported hitherto has its Tc reached this mark at ambient conditions. In other words, the high temperature superconducting states for these materials or compounds neither require being obtained by energy boosting through, but not limited to, external radiation, nor exist transiently for only a short period of time. Also, the high temperature superconducting states exist at atmosphere pressure, meaning they do not require applying additional external pressures.

The chemical formulae or the compositions of the compounds can be written as (M)(X)n, where the M is at least one from the actinide elements, i.e., actinium (Ac), thorium (Th), protactinium (Pa), uranium (U), Neptunium (Np), plutonium (Pu), americium (Am), curium (Cm), berkelium (Bk), californium (Cf), einsteinium (Es), fermium (Fm), mendelevium (Md), nobelium (No), lawrencium (Lr), and their isotopes; the X represents at least one element from fluorine (F), chlorine (Cl), bromine (Br), iodine (I), astatine (At), oxygen (O), sulfur (S), selenium (Se), tellurium (Te), nitrogen (N), phosphorus (P), arsenic (As), antimony (Sb), carbon (C), silicon (Si), germanium (Ge), boron (B) and their isotopes; the n is a value ranging from 0.05 to 20.

Because of the chemical resemblance between groups of actinide and lanthanide (rare earth), the elements from the lanthanide group are also included in this invention and hence the M, hereinbefore, also encompasses lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu) and their isotopes.

In a separate effort on widening the search for the high temperature superconductors, a couple of compounds made by early transition metals were also found. This is because several of these transition metal compounds demonstrated the similar electromagnetic properties of the actinide salts. The properties of these transition metal compounds are very sensitive to their chemical stoichiometry. For instance, TaC_{0.8} (n=0.8) and NbC_{0.8} (n=0.8) both exhibited coexistence of electric conductivity and diamagnetism at room temperature while their property of diamagnetism changes dramatically with slight change of the n values. Therefore these transition elements are assigned to the M for the above formulae of (M)(X)n as the candidates to build the high Tc superconductors of this invention. These transition metals are, scandium (Sc), titanium (Ti), vanadium (V), chromium (Cr), manganese (Mn), yttrium (Y), zirconium (Zr), niobium (Nb), molybdenum (Mo), technetium (Tc), hafnium (Hf), tantalum (Ta) tungsten (W), rhenium (Re) and their isotopes.

Among the aforementioned compounds composed according to the formulae of (M)(X)n, several of them were made in the past but their superconducting property has not been realized hitherto. Consequently, this invention is to repurpose these known compounds, for the first time, as the high temperature superconducting materials. The rest of the compounds, again formulated by (M)(X)n, are new and have never been synthesized heretofore. The second part of this invention is to purpose these new formulated compounds as the candidates of the high temperature superconductors. Again, these new formulated compounds fit the aforementioned formulae of (M)(X)n with the elements for the M and the X defined above as well as the n ranging from 0.05 to 20.

### BACKGROUND

Since the first discovery of the superconductive phenomenon of mercury at its Tc of 4.2 K in 1911, the work of exploring higher and higher Tc superconductors progressed slowly for about 75 years. This slow progress was interjected by the major revolutionary discovery of superconductivity on certain lanthanum based cuprate Perovskite ceramics, the so called type II superconducting materials, in 1986. This finding led the Tc to successfully outreach the milestone of 77 K, i.e., the boiling temperature of liquid nitrogen, at the same year. The further enhancement of Tc on the cuprate Perovskite ceramics via cation and/or anion modifications reached in the vicinity of 138 K in 1995, which is the widely accepted highest world record of Tc hitherto.

It has been almost 30 years after the discovery of the type II superconductivity. Great effort on preparing higher and higher Tc superconductive materials has been made in the hope of exceeding the other two major milestones, viz., the melting point of water (273 K) and the room temperature (298 K). Even though, the studies on certain cuprate Perovskites via an external optic stimulation showed possible room temperature superconductivity, but the results will need to be reconfirmed by different experiments while the reported metastable superconducting state existed too short in a span of several nanoseconds to be used in any application. Theoretically speaking, this super short life time of superconducting state would make other experiments to confirm its existence extremely difficult.

It is of great importance to have a stable superconducting material whose Tc can surpass one or both of the 273 K and 298 K milestones. Technically speaking, the even stricter requirements than the abovementioned two temperature marks of 273 K and 298 K for low power application needs the Tc of superconductor to top 350 K while Tc for high power application should outpace 450 K. A tremendous amount of effort has been made, aiming to accomplish these tasks. Unfortunately, most works have not come close to the milestones while the others that claimed to have room temperature superconductivity were neither confirmed nor accepted by other professionals.

### BRIEF DESCRIPTION OF DRAWINGS

FIG. 1 displays the history of superconductor development by plotting the advances of the superconducting transition (critical) temperature, Tc, in Kelvin (K) against the time in year.

FIG. 2A and FIG. 2B exhibit two geometries for the [ThI₆] structural units: (A) Trigonal-antiprismatic (anti-Pris), and (B) Trigonal-prismatic (Pris).

FIG. 3 highlights the crystallographic unit cell of ThI₂ in a way that two geometries of the [ThI₆] units, i.e., anti-Pris and Pris, are stacked alternatively along c-axis.

FIG. 4A-4D illustrate the orientations of the atomic geometries for each individual layers along the crystallographic c-axis of the ThI₂ hexagonal unit cell as shown in FIG. 3, where the positions (x, y, z) of thorium (Th) cations are (A) (⅔, ⅓, ¾); (B) (0, 0, ½); (C) (⅓, ⅔, ¼); and (D) (0, 0, 0).

FIG. 5A-5D expand the connections of each layer in FIG. 4A-4D into four unit cells relatively and reveal the layered edge-sharing property of ThI₂. The connections in FIG. 5A and FIG. 5C are easy to see and only the side views are given while the extra top views in FIG. 5B and FIG. 5D are included for better visualizing the edge-sharing features of the 4-cell connections of the four [ThI₆] units.

FIG. 6 gives a layout of a typical ThS (NaCl structure) and its layer feature on {111} planes is demonstrated, i.e., the thorium cations (Th) and sulfur anions (S) are packed alternatively.

FIG. 7A reveals the crystal structure of ThS, where the six solid balls, representing sulfur anions (S), are replace by hollow ones, also representing sulfurs, in order to depict the octahedral enclosure of sulfur anions (S) around one thorium cation (Th).

FIG. 7B is an individual [ThS₆] octahedral structural unit stripped from FIG. 7A.

FIG. 8 delineates the geometric arrangement of the ThS with the edge-sharing octahedral units of [ThS₆].

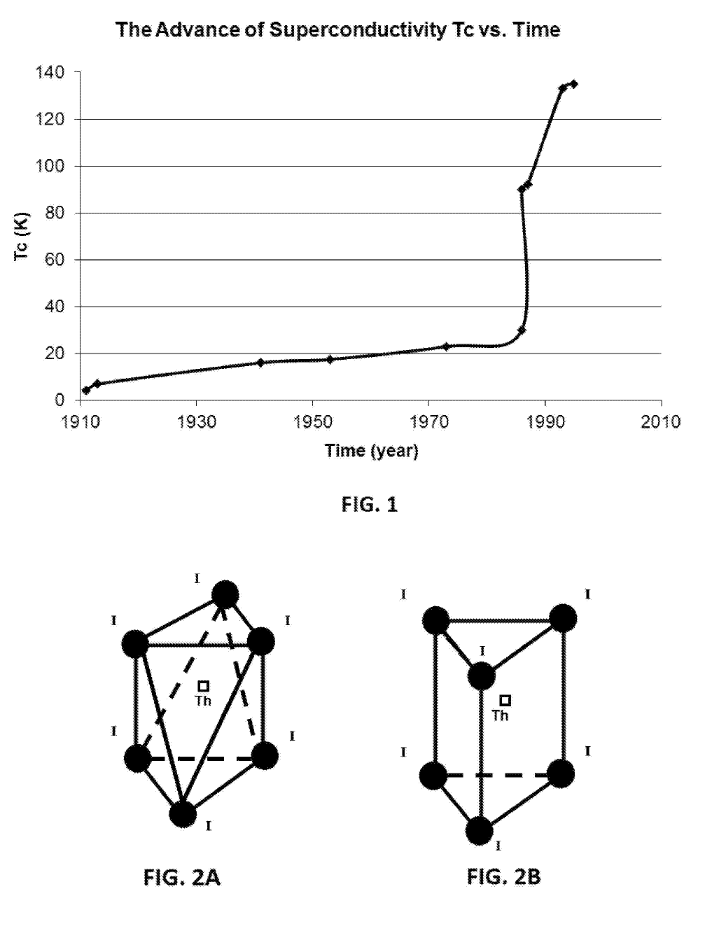

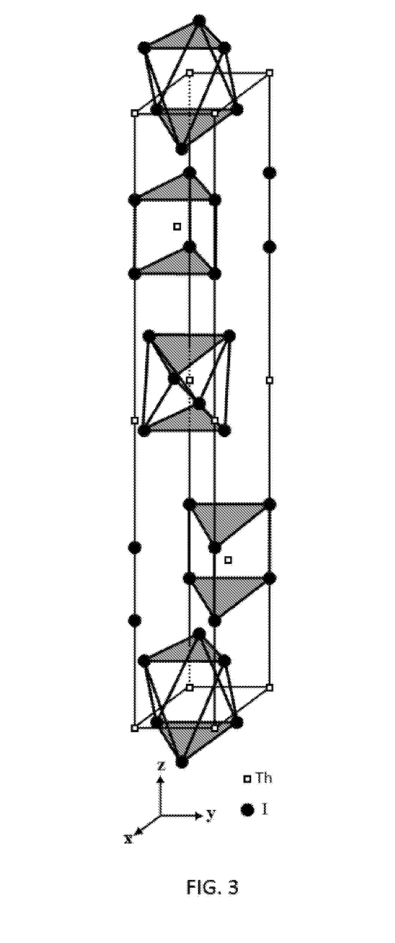

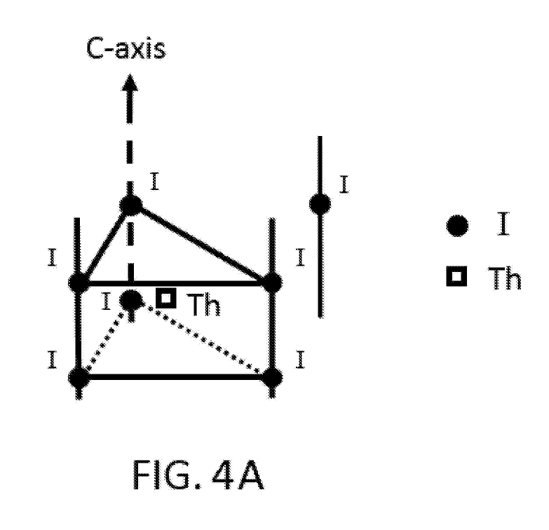

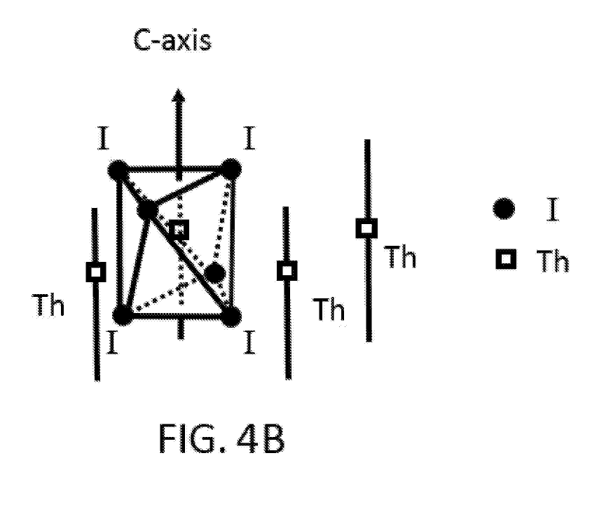

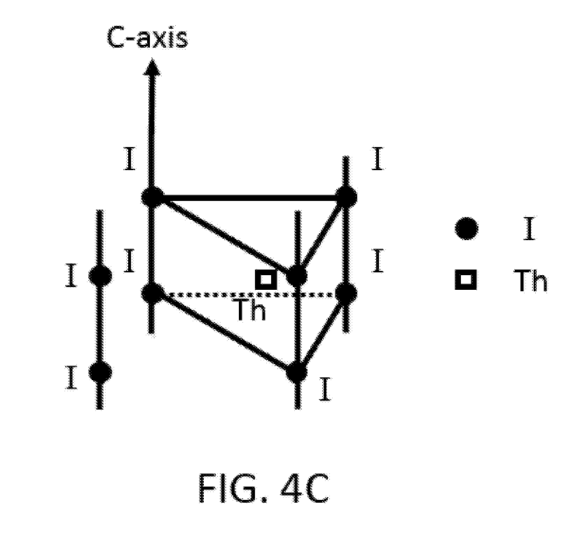

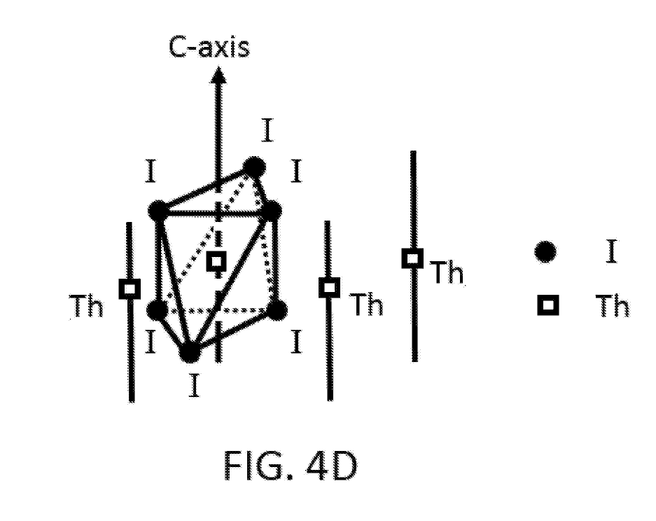

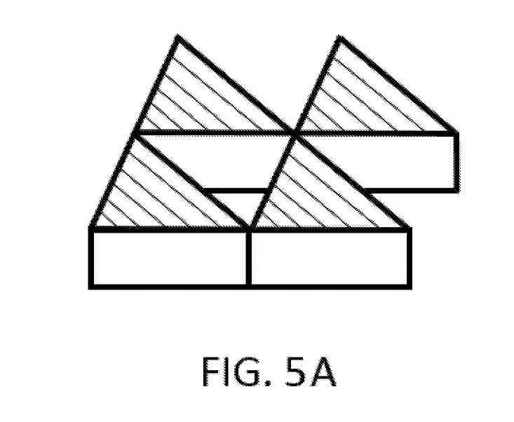

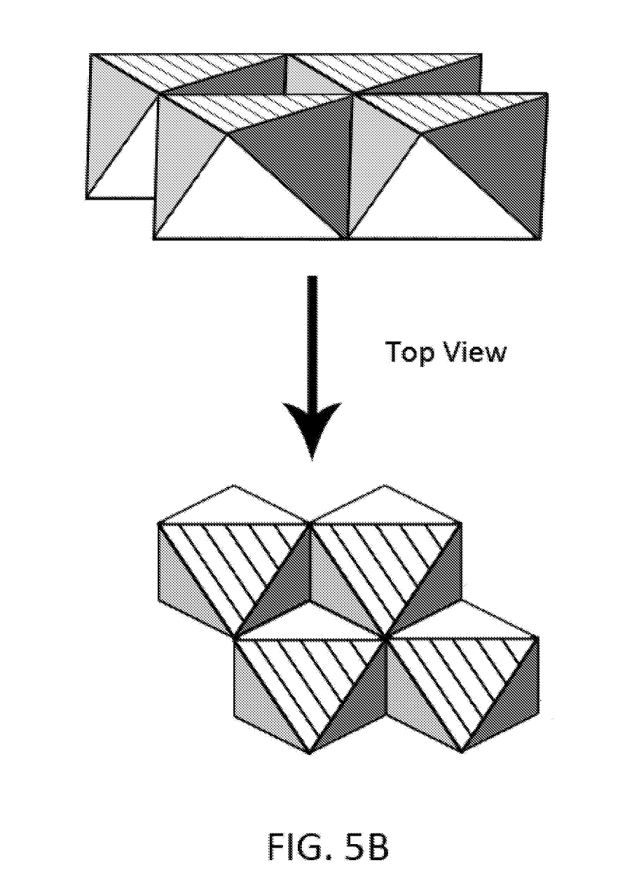

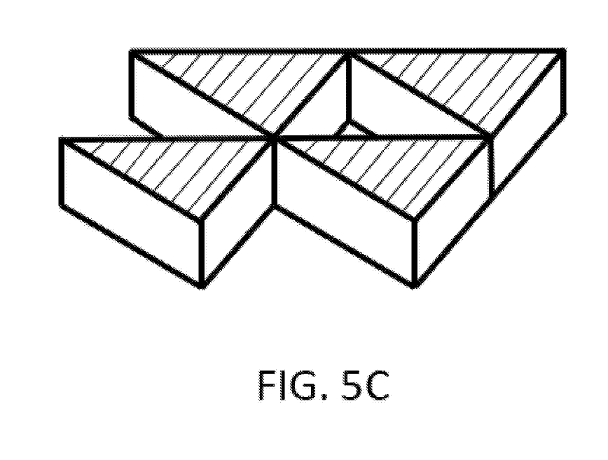

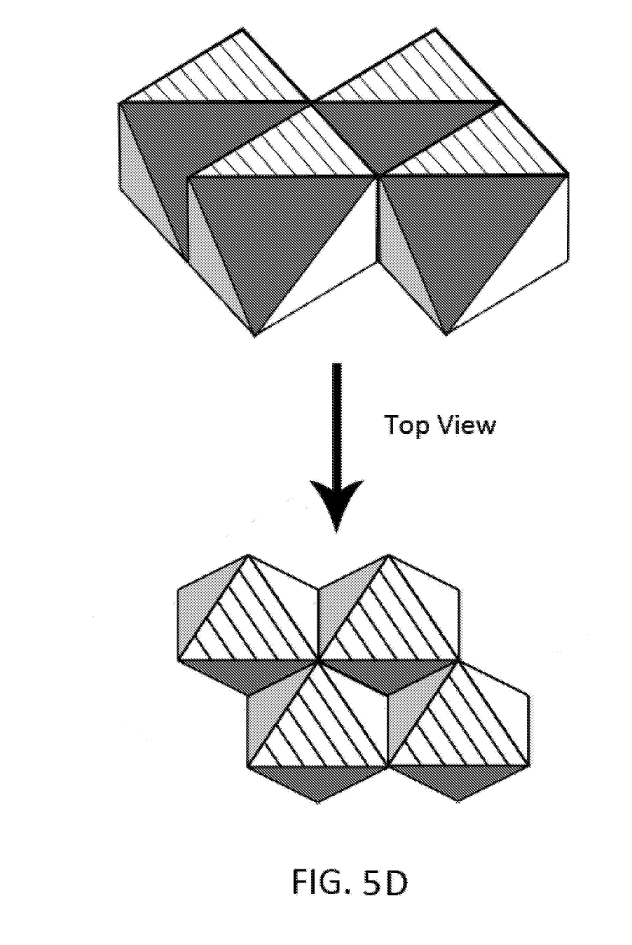

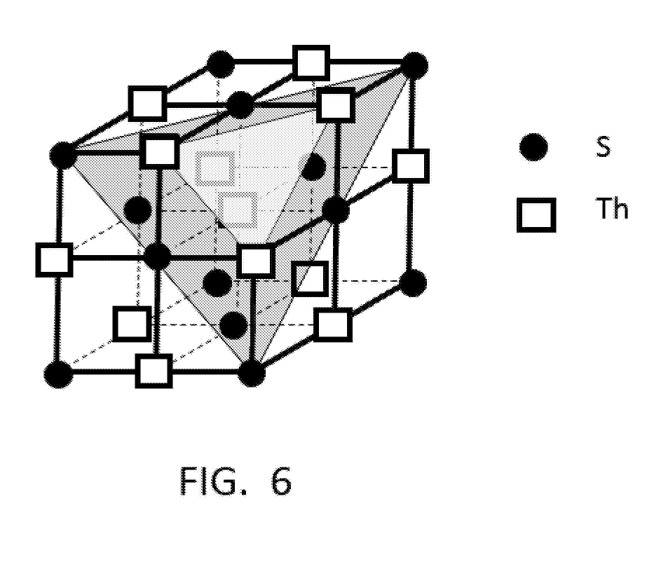

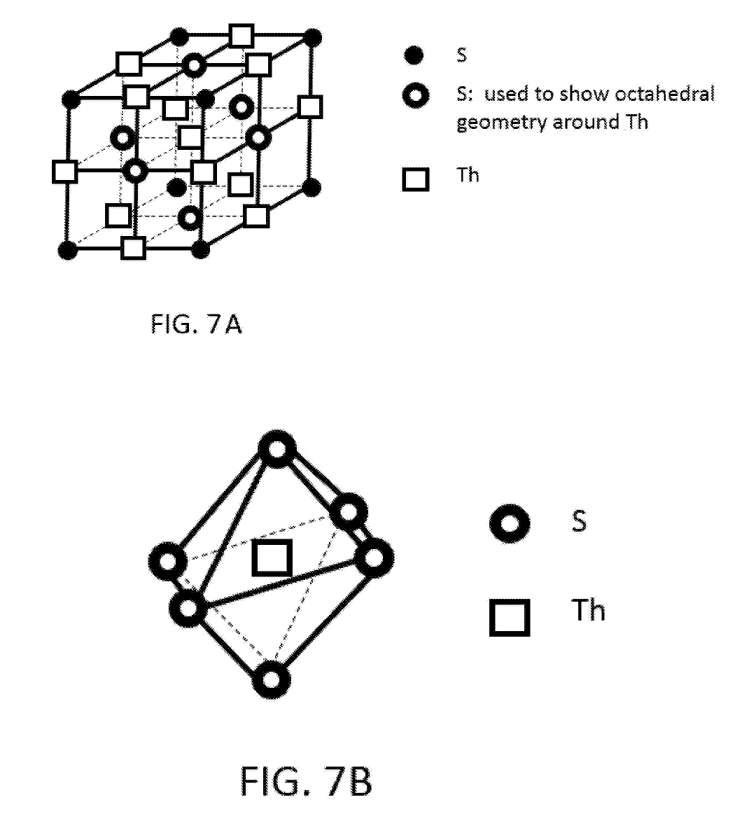

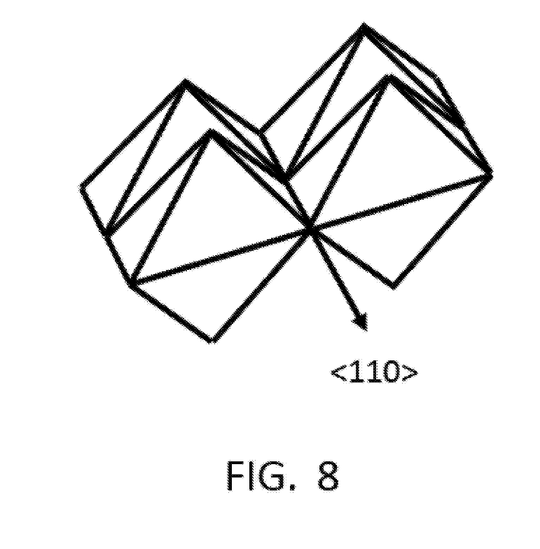

### DETAILED DESCRIPTION

Our approach to accomplish the task of obtaining the high temperature superconductors started with conducting the literature search/research on the previous superconducting materials. We found that the superconducting salts prepared hitherto hardly contain the element(s) from the actinide group. Our subsequent searches on the actinide compounds in the literatures along with our analyses of the compounds' properties and their structural features guided us.

The embodiment of this invention is to exemplify a couple of thorium (Th) salts even though it is not intended to limit the scope of this invention to only the Th compounds.

The majority of the conductive thorium salts were synthesized at around the 1960s. Besides their high electrically conductive feature under room temperature and atmospheric pressure, one of their inimitable properties is their diamagnetic behavior, also at ambient conditions. Notice that this co-existence of electrically conductive and diamagnetic properties is unique to superconductors while normal conductors do not possess these characteristics.

The aforementioned unique feature of the co-existence of both electrically conductive and diamagnetic properties under ambient conditions, i.e., the conditions that the compounds being characterized, hinted us that this group of compounds should have reached their superconducting states at least at room temperature. In other words, these thorium compounds have achieved their superconducting states at room temperature and under atmospheric pressure because of their unique property of co-existence of high electric conductivity and diamagnetism at ambient conditions. Further exploration on how high and/or how low the temperatures, at which the thorium compounds fall into their superconducting states, will need to carry out a completely new round of studies beginning from the syntheses toward high purity of the relative compounds.

Investigations on the structural features of the thorium compounds were also performed. Their X-ray crystallographic results were analyzed, especially for thorium di-iodide (ThI₂) and thorium mono-sulfide (ThS).

ThI₂ crystallized in space group P63/mmc in hexagonal lattice with a-axis of 0.397 nm and an exceptional long c-axis of 3.175 nm. The reason for the long c-axis is because each Th cation is surrounded by 6 I anions in two geometries, i.e., trigonal-antiprismatic (anti-Pris) and trigonal-prismatic (Pris) arrangements. Each hexagonal cell consists of four layers of them along c-axis packed in an alternating manner, i.e., anti-Pris/Pris/anti-Pris/Pris. Each individual trigonal-prismatic or trigonal-antiprismatic of their pairs in a crystallographic unit cell is located at different cell positions and different orientations on their (0001) planes, i.e., atoms of trigonal-prismatic (or trigonal-antiprismatic) having different x and y values relative to another trigonal-prismatic (or trigonal-antiprismatic) of their pairs in the lattice. We re-plotted its unit cell and its individual [ThI₆] structures layer by layer, and we also expanded the plotting of each layer into 4 unit cells. The 4-cell plotting exhibited the planar structure through joining the common edges of either trigonal-antiprismatic or trigonal-prismatic [ThI₆] structural units to construct the two dimensional layered linkage running on the planes parallel to the c-axis. The structural feature of this layered edge sharing connections has also been observed in the crystallographic packing style of other superconductors. This means compound ThI₂ meets the structural criterion for being a superconducting material.

ThS has similar electromagnetic properties as ThI₂ but its crystal structure is cubic, same as the packing of sodium chloride (NaCl), with a=0.568 nm. Its crystallographic structure also revealed the two dimensional layered linkage along <110> directions with edge-sharing characters assembled by the structural units of the [ThS₆] octahedra. The character of this crystallographic layered packing for the ThS compound, again, qualifies the structural demand as a superconductor.

Instead of iodide and sulfide, the co-existence of electric conductivity and diamagnetism associated with actinide compounds, especially for thorium compounds, at relatively high temperature may also be found for their carbide, nitride, boride, etc., as well as their combinations, such as carbonitride. These compounds can also become the candidates for the high temperature superconducting materials of this invention.

It is reported that ThC_{0.78}N_{0.22} is a superconductor but its Tc is too low at about 5.8 K. This compound does not have the property of co-existence of both electric conductivity and diamagnetism at 151 K or higher. Therefore, this compound cannot become the candidate for this invention, even though its molecular formula falls into the (M)(X)n compositions as remarked in this disclosure. In other words, only these compounds that fit the formulae of (M)(X)n described hereinbefore and have their Tc of 151 K or higher belong to the superconductors of this invention. Moreover, compound ThC_{0.78}N_{0.22} fits the formulae of (M)(X)n in a way that M=Th, X═C_{n-0.22}N_{n-0.78}, viz, the binary anion, and n=1.

### Routes of Syntheses of the High Temperature Superconductors

The previous synthetic work of the conductive Th compounds in the 1960s ended up with about 5% impurities by weight. The majority of the impurities were confirmed non-stoichiometric species and Th oxides. This means the new synthetic pathways may require the use of more sophisticated facilities and probably through new reaction procedures. The reasons for these changes are on the purpose of controlling the stoichiometry of the syntheses as well as avoiding the oxidation and/or contamination by oxygen and water under high synthetic temperatures, i.e., up to 2200° C., with or without employing vacuum or inert atmosphere techniques in order to obtain the pure compounds. These harsh requirements may impose difficulties on the new synthetic processes while the reaction methods and procedures may need to be modified and optimized over time. The examples of synthetic routes, hereinafter, are only used to exemplify the ideal situation that the superconducting materials can be made stoichiometrically without oxygen or water oxidation. The further exploration on optimizing the synthetic methods for preparing the high purity of the high temperature superconducting compounds is beyond the scope of this invention.

High temperature solid state reaction can be utilized for this invention. Thorium as one of the most studied elements in the actinide group will be described here while ThS will be exploited as the example in this disclosure.

Albeit many methods of synthesizing thorium sulfide were reported, only three major preparative routes for ThS were utilized here to show the basic ways on making this compound, i.e., two-step synthesis, one-step method and metal hydride technique.

### PROPHETIC EXAMPLE 1

### Two-Step Route

The two-step synthetic route requires the first preparation of thorium di-sulfide (ThS₂) as the starting material for the second step.

ThS₂ can be made by reacting Th metal with excess amount of hydrogen sulfide (H₂S) under vacuum at around 1200-1500° C. The duration of the reaction was not reported but the chemical reaction was claimed to be very fast for the finely thorium metal particles.

ThS can thus be synthesized by mixing the stoichiometric amount of ThS₂ and Th metal, and then heating to 2000-2200° C. under vacuum.

### PROPHETIC EXAMPLE 2

### One-Step Route

Heating the mixture of thorium metal and proper amount of H₂S to about 2000° C. under reduced pressure could produce ThS.

One-step route is relatively simple but the control of the stoichiometry of the reactants to produce the pure ThS may be challenging.

### PROPHETIC EXAMPLE 3

### Thorium Hydride as Starting Material

The reaction to form thorium hydride (ThH₂) proceeds relatively easy depending on the temperature. For converting 300 grams of thorium metal into thorium hydride, the duration is about 10 hours at 300° C. But the time duration can be reduced to only a few minutes if the temperature is increased to 400-500° C. initially and then decreased to 300° C. after the reaction starts.

Thorium hydride is then allowed to react with stoichiometric amount of hydrogen sulfide (H₂S) at around 400-500° C. to generate ThS.

Superconductor Utilities:
1. Superconducting magnet.
2. Magnetic sensors, superconducting quantum interference device (SQUID).
3. Single flux quantum device (SFQ) and its applications such as used as logical circuits for high speed, low power consumption circuits.
4. Energy Storage: Friction-free flywheel-type electricity storage system.
5. Magnetic pinning can create very high magnetic field that can be used for water cleaning system. (100 times efficiency)
6. Magnetically levitated transportation system (MEGLEV).
7. Continuous casting systems in steel mills.
8. High-power motors for ship propulsion systems.
9. Superconducting magnetic energy storage (SMES) system.
10. Other sensor applications such as temperature, pressure, chemical and biological sensors.
11. For no energy lose transportation of electricity.
12. For application of integrated circuit, to avoid the generation of excess heat.
13. By processing chip using superconducting lines to interconnect their different functions, it will dramatically speed up the rate at which they could process data. This could result in impressive improvement in the performance of high frequency and high speed circuits.
14. Multiple magnet system for magnetic ore separation.
15. Nuclear magnetic resonance (NMR) and magnetic resonance imaging (MRI).
16. Superconducting quadrupoles for a beam line of decaying particles.
17. For the electrode materials or composite of electrode materials to enhance conductivity.
18. Superconducting toys
19. Compact superconducting motors would replace noisy, polluting engines.
20. Memory/Storage element (persistent current)
21. Highly efficient small sized electrical generator and transformer
22. Large distance power transmission (ρ=0)
23. Switching device (easy destruction of superconductivity)
24. Superconducting solenoids—magneto hydrodynamic power generation—plasma maintenance
25. Separate damaged cells and healthy cells-medical application
26. Diagnosis of brain tumor
27. Magneto—hydrodynamic power generation
28. Uses of Josephson devices: magnetic sensors, gradiometers, oscilloscopes, decoders, analog to digital converters, oscillators, microwave amplifiers, sensors for biomedical, scientific and defense purposes, digital circuit, development for integrated circuits, microprocessors, random access memories (RAMs).
29. High frequency and high speed circuits.
30. Passive RF and microwave filter for wide-band communications and radars. Very low noise and much higher selectivity and efficiency than conventional filters.
31. Quantum computing circuits.
32. Superconducting tunnel junction (STJ) is the most heterodyne receivers in 100 GHz to 1000 GHz frequency range.

1. A device including a material that conducts electricity, the material comprising:
a compound with a chemical formula (M)(X)ₙ;
wherein M is at least one selected from the group consisting of: actinium, thorium, protactinium, uranium, neptunium, plutonium, americium, curium, berkelium, californium, einsteinium, fermium, mendelevium, nobelium, lawrencium, lanthanum, cerium, praseodymium, neodymium, promethium, samarium, europium, gadolinium, terbium, dysprosium, holmium, erbium, thulium, ytterbium, lutetium, scandium, titanium, vanadium, chromium, manganese, yttrium, zirconium, niobium, molybdenum, technetium, hafnium, tantalum, tungsten, rhenium, and their isotopes;
wherein X is at least one selected from the group consisting of: fluorine, chlorine, bromine, iodine, astatine, oxygen, sulfur, selenium, tellurium, nitrogen, phosphorus, arsenic, antimony, carbon, silicon, germanium, boron, and their isotopes; and
n is a value ranging from 0.05 to 20; and
the compound conducts electricity at 151 K or higher.

2. The device including a material that conducts electricity of claim 1, wherein M is two or more elements selected from the group consisting of: actinium, thorium, protactinium, uranium, neptunium, plutonium, americium, curium, berkelium, californium, einsteinium, fermium, mendelevium, nobelium, lawrencium, lanthanum, cerium, praseodymium, neodymium, promethium, samarium, europium, gadolinium, terbium, dysprosium, holmium, erbium, thulium, ytterbium, lutetium, scandium, titanium, vanadium, chromium, manganese, yttrium, zirconium, niobium, molybdenum, technetium, hafnium, tantalum, tungsten, rhenium, and their isotopes; and
X includes two or more anions selected from the group consisting of: fluorine, chlorine, bromine, iodine, astatine, oxygen, sulfur, selenium, tellurium, nitrogen, phosphorus, arsenic, antimony, carbon, silicon, germanium, boron, and their isotopes.

3. The device including a material that conducts electricity of claim 1, wherein the compound is selected from the group consisting of: ThI₂, ThS, TaC_{0.8}, NbC_{0.8}, Ti(C)n, Zr(C)n, Hf(C)n and V(C)n.

4. The device including a material that conducts electricity of claim 1, wherein the material has a layered molecular configuration connected through repeating structural units or coordination polyhedrons centered by metallic atoms.

5. The device including a material that conducts electricity of claim 1, wherein the material is in the form selected from the group consisting of: single crystal, polycrystalline, amorphous, or bulk, thin film or single molecular layer.

6. The device including a material that conducts electricity of claim 1, wherein the material is stable without application of external energy.

7. The device including a material that conducts electricity of claim 1, wherein the compound has a crystalline structure selected from the group consisting of cubic or hexagonal with coordination geometries of trigonal-antiprismatic or trigonal-prismatic or octahedral or cubic.

8. The device including a material that conducts electricity of claim 1, wherein the material is diamagnetic at 151 K or higher.

9. The device including a material that conducts electricity of claim 1, wherein the device selected from the group consisting of:
a magnetic device, a sensor, a quantum interference device, a single flux quantum device, a logic circuit, an energy storage device, a water cleaning system, a magnetically levitated transportation system, a continuous casting device, a motor, a magnetic ore separator device, a device for transporting electricity, an integrated circuit, a processor chip, an NMR, an MRI, a quadrupole, an electrode, a toy, a memory storage element with persistent current, an electrical generator, an electrical transformer, an electrical switching device, a solenoid, a medical device to separate healthy and damaged cells, a diagnostic medical device to diagnose tumors, a magneto-hydrodynamic power generator, a Josephson device, a microprocessor, random access memory, a digital circuit, a magnetic sensor, a gradiometer, an oscilloscope, a decoder, an analog to digital converter, an oscillator, a microwave amplifier, a passive RF and microwave filter, a quantum computing circuit, and a tunnel junction.

10. The device including a material that conducts electricity of claim 1, wherein the device is selected from the group consisting of:
a logic circuit, a device for transporting electricity, an integrated circuit, a memory storage element with persistent current, an electrical switching device, a microprocessor, a random access memory, a digital circuit, a quantum computing circuit, and a tunnel junction.

11. The device including a material that conducts electricity of claim 1, wherein the device is selected from the group consisting of:
a magnetic device, an energy storage device, a motor, a magnetic ore separator device, an electrode, an electrical generator, an electrical transformer, and a solenoid.

12. The device including a material that conducts electricity of claim 1, wherein the device is a processor chip wherein the electrically conducting lines on the chip comprise the material.

13. The device including a material that conducts electricity of claim 1, wherein the device is selected from the group consisting of:
a sensor, a quantum interference device, a single flux quantum device, a water cleaning system, a magnetically levitated transportation system, a continuous casting device, a magnetic ore separator device, an NMR, an MRI, a quadrupole, a toy, a medical device to separate healthy and damaged cells, a diagnostic medical device to diagnose tumors, a magneto-hydrodynamic power generator, a gradiometer, an oscilloscope, a decoder, an analog to digital converter, an oscillator, a microwave amplifier, a passive RF and microwave filter, and a quantum computing circuit.

14. The device including a material that conducts electricity of claim 1, wherein the material is without oxygen or water oxidation.

15. The device including a material that conducts electricity of claim 1, wherein the material is selected to be diamagnetic.

16. The device including a material that conducts electricity of claim 1, wherein the compound is selected from the group consisting of ThI₂ and ThS,

17. The device including a material that conducts electricity of claim 1, wherein the compound is ThS.

18. The device including a material that conducts electricity of claim 1, wherein the compound is ThI₂.

19. The device including a material that conducts electricity of claim 16, wherein the device is selected from the group consisting of:
a logic circuit, a device for transporting electricity, an integrated circuit, a memory storage element with persistent current, an electrical switching device, a microprocessor, a random access memory, a digital circuit, a quantum computing circuit, and a tunnel junction.

20. The device including a material that conducts electricity of claim 15, wherein the compound is selected from the group consisting of ThI₂ and ThS.
